(19) United States
(12) Patent Application Publication
(10) Pub. No.: US 2025/0126751 A1
(43) Pub. Date: Apr. 17, 2025

(54) SYSTEMS AND METHODS FOR THREE-DIMENSIONAL HEAT TRANSFER ARCHITECTURES MANUFACTURED BY SELECTIVE PLATING

(71) Applicant: Meta Platforms Technologies, LLC, Menlo Park, CA (US)

(72) Inventors: Brian Toleno, Cupertino, CA (US); Michael Nikkhoo, Saratoga, CA (US)

(73) Assignee: Meta Platforms Technologies, LLC, Menlo Park, CA (US)

(21) Appl. No.: 18/912,470

(22) Filed: Oct. 10, 2024

Related U.S. Application Data
(60) Provisional application No. 63/544,594, filed on Oct. 17, 2023.

(51) Int. Cl. H05K 7/20

(52) U.S. Cl. CPC H05K 7/20336

(57) ABSTRACT

A method for constructing heat transfer architectures for use in wearables or other small electronic devices using selective micro plating to quickly and precisely generate complex 3D microstructures, a heat transfer architecture, and electronic device with a heat transfer architecture includes creating capillary wick structures, wherein the capillary wick structures may vary in characteristics. An interface may be generated with a vessel wall to provide an optimal interface between the capillary wick structures and the vessel wall.

### RELATED CASES

This application claims the benefit of U.S. Provisional Application No. 63/544,594 filed on 17 Oct. 2023, the contents of which are all incorporated by reference.

### BACKGROUND

Capillary wick structures are typically made from sintered mesh, fiber/filaments, and the like. These solutions are often off the shelf and do not lend themselves to optimum performance, as feature types and sizes cannot be fine-tuned.

These features vary as a function of temperature and metrics driven by evaporator, condense and the adiabatic region. As an example, the evaporator region needs very fine hydrophilic features whereas the condenser area is exactly the opposite.

Thus, extra unnecessary overhead ensues, e.g., weight and Qmax (power) and one of the key metrics, namely, temperature drop across vessel is often ignored. In the wearable space, it's the temperature drop that's key, as dictated by human interface/COMFORT and boundary conditions.

More particularly, existing heat transfer architectures such as heat pipes, vapor chambers, heat sinks, and the like are well suited for transferring large amounts of heat, but existing architectures have relatively large form factors that are not suitable for wearable devices. Attempts to scale down the size of conventional heat transfer architectures have proved difficult, expensive, and shown low repeatability. In order to deal with the greater amounts of heat generated from ever more powerful wearable devices, smaller, lighter, and more efficient heat transfer architectures are needed.

### SUMMARY

In one example implementation, a method for constructing heat transfer architectures for use in wearables or other small electronic devices using selective micro plating to quickly and precisely generate complex 3D microstructures, may include but is not limited to creating capillary wick structures, wherein the capillary wick structures may vary in characteristics. An interface may be generated with a vessel wall to provide an optimal interface between the capillary wick structures and the vessel wall.

One or more of the following example features may be included. The characteristics may include at least one of porosity, surface finish, hydrophilicity/hydrophobicity, surface tension, and capillary action. The capillary wick structures may vary in characteristics along a length of a heat pipe of the capillary wick structures. The capillary wick structures may vary in characteristics over an area of a vapor chamber of the capillary wick structures, wherein the characteristics may include a pore size that is varied over a length of the vapor chamber. The selective micro plating may be performed on a flat conductive surface and used to generate the capillary wick structures having complex three-dimensional (3D) geometries. At least a portion of the heat transfer architectures may be shaped in 3D to conform to a shape/elevation of components on a Printed Circuit Board (PCB). Thermal dissipation whiskers protruding from the heat transfer architectures may be added to increase surface area.

In another example implementation, a heat transfer architecture for use in wearables or other small electronic devices using selective micro plating to quickly and precisely generate complex 3D microstructures may include but is not limited to capillary wick structures, wherein the capillary wick structures may vary in characteristics. The heat transfer architecture may further include an interface with a vessel wall to provide an optimal interface between the capillary wick structures and the vessel wall.

One or more of the following example features may be included. The characteristics may include at least one of porosity, surface finish, hydrophilicity/hydrophobicity, surface tension, and capillary action. The capillary wick structures may vary in characteristics along a length of a heat pipe of the capillary wick structures. The capillary wick structures may vary in characteristics over an area of a vapor chamber of the capillary wick structures, wherein the characteristics may include a pore size that is varied over a length of the vapor chamber. The selective micro plating may be performed on a flat conductive surface and used to generate the capillary wick structures having complex three-dimensional (3D) geometries. At least a portion of the heat transfer architectures may be shaped in 3D to conform to a shape/elevation of components on a Printed Circuit Board (PCB). Thermal dissipation whiskers protruding from the heat transfer architectures may be added to increase surface area.

In another example implementation, an electronic device with a heat transfer architecture may include but is not limited to an electronic device, wherein the electronic device may include capillary wick structures, wherein the capillary wick structures may vary in characteristics. The heat transfer architecture may further include an interface with a vessel wall to provide an optimal interface between the capillary wick structures and the vessel wall.

One or more of the following example features may be included. The characteristics may include at least one of porosity, surface finish, hydrophilicity/hydrophobicity, surface tension, and capillary action. The capillary wick structures may vary in characteristics along a length of a heat pipe of the capillary wick structures. The capillary wick structures may vary in characteristics over an area of a vapor chamber of the capillary wick structures, wherein the characteristics may include a pore size that is varied over a length of the vapor chamber. The selective micro plating may be performed on a flat conductive surface and used to generate the capillary wick structures having complex three-dimensional (3D) geometries. At least a portion of the heat transfer architectures may be shaped in 3D to conform to a shape/elevation of components on a Printed Circuit Board (PCB). Thermal dissipation whiskers protruding from the heat transfer architectures may be added to increase surface area.

The details of one or more example implementations are set forth in the accompanying drawings and the description below. Other possible example features and/or possible example advantages will become apparent from the description, the drawings, and the claims. Some implementations may not have those possible example features and/or possible example advantages, and such possible example features and/or possible example advantages may not necessarily be required of some implementations.

### BRIEF DESCRIPTION OF DRAWINGS

FIG. 1 are example wick/capillary structures according to one or more example implementations of the disclosure;

FIG. 2 is an example view of copper plating (digitized) according to one or more example implementations of the disclosure;

FIG. 3 is an example image of super fine features and hollow networks with high permeability according to one or more example implementations of the disclosure;

FIG. 4 is an example image of fine hydrophilic “wells” for the evaporator region and much larger hydrophobic structures for the condenser region can be printed on the same platform according to one or more example implementations of the disclosure; and

FIG. 5 is an example image of a High-Resolution Ultra-Precise Features in Pure Metal according to one or more example implementations of the disclosure; and

FIG. 6 is an example image of complex lattice structures for light-weighting designs and maximizing surface area according to one or more example implementations of the disclosure; and

FIG. 7 is an example flowchart of a manufacturing process according to one or more example implementations of the disclosure.

Like reference symbols in the various drawings may indicate like elements.

### DESCRIPTION

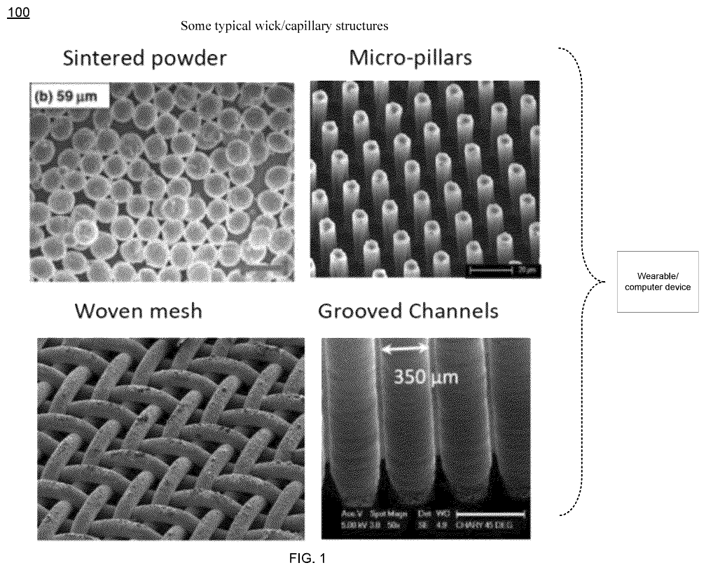

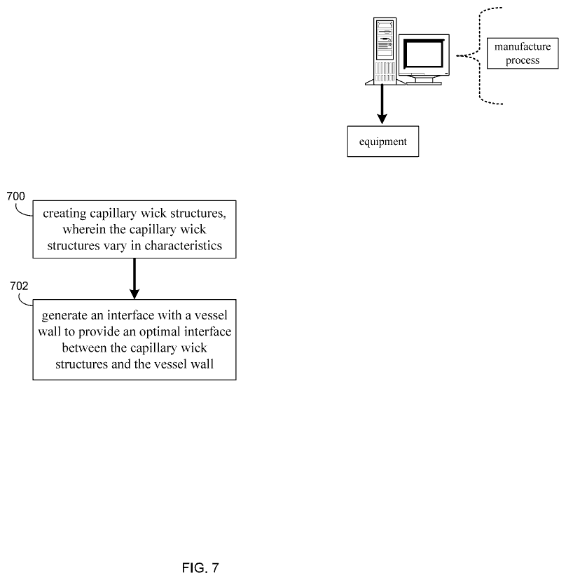

As discussed above and referring also at least to the example implementations of FIGS. 1-7, a method for constructing heat transfer architectures for use in wearables or other small electronic devices using selective micro plating to quickly and precisely generate complex 3D microstructures, may include but is not limited to creating 700 capillary wick structures, wherein the capillary wick structures may vary in characteristics. An interface may be generated 702 with a vessel wall to provide an optimal interface between the capillary wick structures and the vessel wall.

In some implementations, a method for constructing heat transfer architectures for use in wearables or other small electronic devices using selective micro plating to quickly and precisely generate complex 3D microstructures, may include creating 700 capillary wick structures, wherein the capillary wick structures may vary in characteristics, and in some implementations, an interface may be generated 702 with a vessel wall to provide an optimal interface between the capillary wick structures and the vessel wall. For example, the present disclosure relates to techniques for constructing small, lightweight, and more efficient heat transfer architectures using selective micro plating to quickly and precisely generate complex 3D microstructures (e.g., at resolutions in the range of, for example, 30-70 microns). The techniques enable creation of highly efficient capillary wick structures (the engines within heat pipes and vapor chambers) in a way that is fast, precise, and repeatable. For example, and referring at least to the example implementation of FIG. 1, there is shown example wick/capillary structures 100 according to one or more example implementations of the disclosure. There are high-resolution, 3D metal printing electrochemical additive manufacturing processes. With additive print technology, fine features can be printed up on a substrate and porous structures with high permeability can be created. Furthermore, structures can be printed to various elevations akin to city skyline and thus bring additional leverage to this design/process.

In some implementations, the characteristics may include at least one of porosity, surface finish, hydrophilicity/hydrophobicity, surface tension, and capillary action. For example, in some implementations, the capillary wick structures may vary in characteristics along a length of a heat pipe of the capillary wick structures, and in some implementations, the capillary wick structures may vary in characteristics over an area of a vapor chamber of the capillary wick structures, wherein the characteristics may include a pore size that is varied over a length of the vapor chamber. For instance, unlike previous solutions to scale down the size of heat pipes and vapor chambers, selective micro plating allow creation of wick structures that vary in characteristics (porosity, surface finish, hydrophilicity/hydrophobicity, surface tension, capillary action, etc.) along the length of the heat pipe or over the area of the vapor chamber. For example, the process allows for creation of hydrophobic features on the cold side, channels with low pressure drop in the middle, and then hydrophilic features on the hot side. Each zone can be fine-tuned with mechanical features and optimized to a particular operating temperature range and/or power level.

The techniques provide, for example, heat transfer architectures that have improved thermal temp reduction. These techniques enable creation of tiny heat pipes and vapor chambers that can be used to efficiently transfer and disperse heat within wearable devices and other small electronic devices. The techniques also provide, for example, heat transfer architectures that have improved flexibility.

In some implementations, the selective micro plating may be performed on a flat conductive surface and used to generate the capillary wick structures having complex three-dimensional (3D) geometries. For instance, selective micro plating may be performed on any flat conductive surface and may be used to generate wicks having complex three-dimensional (3D) geometries. The techniques further provide, for example, heat transfer architectures that have improved strength. Grain size of parts made using this plating process is on the order of, for example, 2 microns, which provides a much cleaner and stronger structure than structures made by extrusion or other formation processes. The techniques provide, for example, heat transfer architectures that have high yield and repeatability. Existing approaches to reduce the size of heat pipes and vapor chambers require insertion of delicate filaments into a vessel, and are susceptible to high rates of failure or damage to the wick during manufacturing. Because of the high resolution and precise feature formation process using selective micro plating, virtually every heat pipe or vapor chamber formed will be functional. The techniques also provide, for example, heat transfer architectures that have improved speed from design to production because the parts are essentially printed from a 3D model, the time from design to production is very short.

The techniques further much more precise, controllable, known wick structure. Allows one to generate a known interface with the wall, to provide an optimal wall function (interface between the wick and the vessel wall). By comparison, the old mesh structure one does not really know how exactly the meshes will come together, so one cannot control the quality. Also, the meshes do not meet the wall cleanly, which reduces performance of the engine.

In some implementations, at least a portion of the heat transfer architectures may be shaped in 3D to conform to a shape/elevation of components on a Printed Circuit Board (PCB). For instance, the shape of the heat transfer architecture can be entirely custom. The heat transfer architecture may be shaped in 3D to conform to the shape/elevation of components on the PCB. This allows one to minimize the gaps between chips/heat sources and the vapor chamber. Furthermore, one can customize the pore size and vary it over the length of the vapor chamber (e.g., big asymmetrical pyramids or triangles on the cold size to push the water away, transition to channels optimized for transmission to the condenser side, transition to tiny wells (40-70 microns) at the hot side). In some implementations, thermal dissipation whiskers protruding from the heat transfer architectures may be added to increase surface area. For instance, thermal dissipation whiskers protruding from heat sink may also be added to increase surface area.

One example structure may include coarse channels (100-150 microns), a layer of fine mesh over the top (e.g., 75 microns), and a layer of finer mesh over top (30-50 microns). This example structure may be in the form of one continuous structure. This example structure may have discrete regions, or may continuously vary over the thickness. Another example structure may include channels having a triangular cross section (triangles provide acute angles that increase the capillary action of the channels).

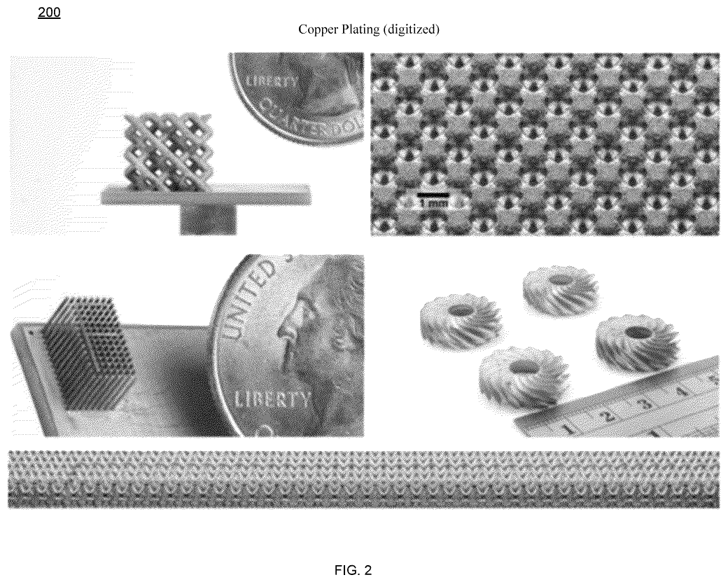

Referring at least to the example implementation of FIG. 2, there is shown an example view of copper plating (digitized) 200 according to one or more example implementations of the disclosure.

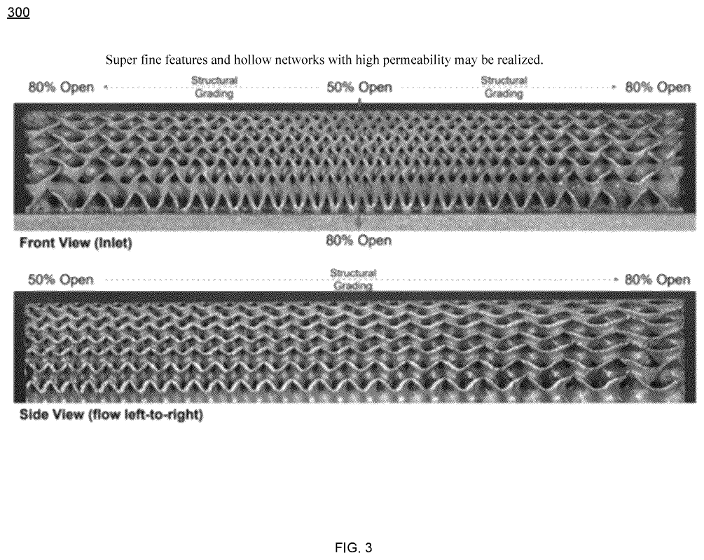

Referring at least to the example implementation of FIG. 3, there is an example view 300 of super fine features and hollow networks with high permeability according to one or more example implementations of the disclosure.

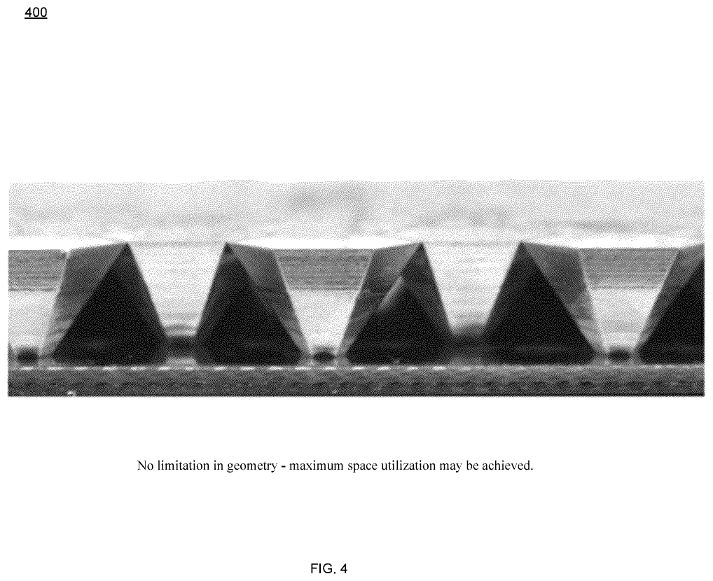

Referring at least to the example implementation of FIG. 4, there is shown an example view 400 of fine hydrophilic “wells” for the evaporator region and much larger hydrophobic structures for the condenser region can be printed on the same platform according to one or more example implementations of the disclosure. Customized fine hydrophilic “wells” for the evaporator region and much larger hydrophobic structures for the condenser region can be printed on the same platform. There is no limitation in geometry-maximum space utilization may be achieved.

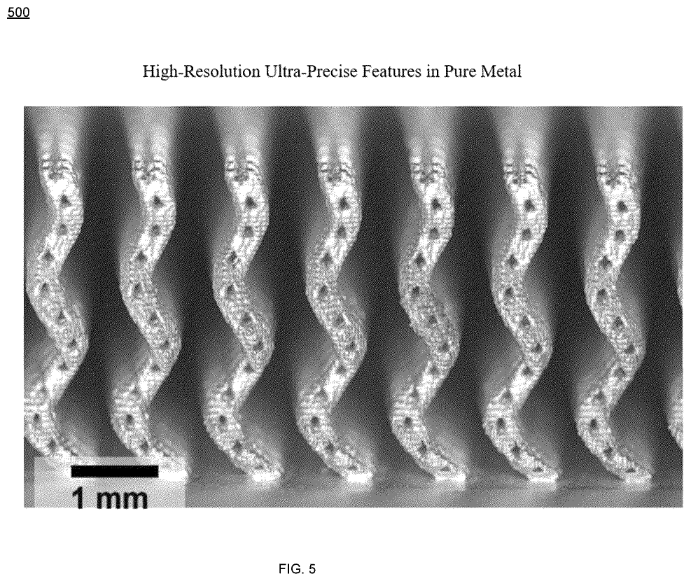

Referring at least to the example implementation of FIG. 5, there is shown an example image 500 of High-Resolution Ultra-Precise Features in Pure Metal according to one or more example implementations of the disclosure.

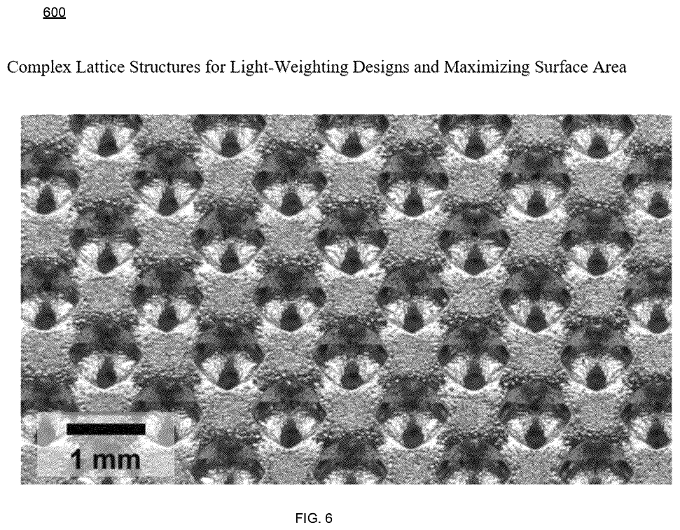

Referring at least to the example implementation of FIG. 6, there is shown an example of complex lattice structures 600 for light-weighting designs and maximizing surface area according to one or more example implementations of the disclosure. Thus, given the resolution of this process, the heat architecture may be tuned to provide maximum power with lowest temperature rise across the device. Evaporative cells may be optimized to reduce evaporative resistance. Condenser cells may be optimized to promote hydrophobicity. Fine features such as fins may be printed directly onto thermal ground planes (TGPs) or other thermals solutions and thus optimize weight, part count, improved thermal performance, and packaging efficiency-which may be beneficial particularly in wearable/VR space. Additionally, the techniques provide for good feature resolution, high aspect ratios, low surface roughness, high purity and performance, and direct-write to printed circuit boards (PCBs)/silicon.

It will be appreciated after reading the present disclosure that any standard assembly/printing/fabrication, etc. equipment, as well as any other necessary equipment, and any particular location, such as at a foundry, fabrication facility, etc. may be used singly or in any combination with the present disclosure, which may be operatively connected to a computing device, to obtain their instructions for creating and/or executing one or more aspects of the present disclosure. In one or more example implementations, the respective flowcharts may be manually implemented, computer-implemented, or a combination thereof.

The terminology used herein is for the purpose of describing particular implementations only and is not intended to be limiting of the disclosure. As used herein, the singular forms “a”, “an” and “the” are intended to include the plural forms as well, including any steps performed by a/the computer/processor, unless the context clearly indicates otherwise. As used herein, the phrase “at least one of A, B, and C” should be construed to mean a logical (A OR B OR C), using a non-exclusive logical OR, and should not be construed to mean “at least one of A, at least one of B, and at least one of C.” As another example, the language “at least one of A and B” (and the like) as well as “at least one of A or B” (and the like) should be interpreted as covering only A, only B, or both A and B, unless the context clearly indicates otherwise. It will be further understood that the terms “comprises” and/or “comprising,” when used in this specification, specify the presence of stated features, integers, steps (not necessarily in a particular order), operations, elements, and/or components, but do not preclude the presence or addition of one or more other features, integers, steps (not necessarily in a particular order), operations, elements, components, and/or groups thereof. Example sizes/models/values/ranges can have been given, although examples are not limited to the same.

The terms (and those similar to) “coupled,” “attached,” “connected,” “adjoining,” “transmitting,” “communicating,” “receiving,” “connected,” “engaged,” “adjacent,” “next to,” “on top of,” “above,” “below,” “abutting,” and “disposed,” used herein is to refer to any type of relationship, direct or indirect, between the components in question, and may apply to electrical, mechanical, fluid, optical, electromagnetic, electromechanical or other connections, including logical connections via intermediate components (e.g., device A may be coupled to device C via device B). Additionally, the terms “first,” “second,” etc. are used herein only to facilitate discussion, and carry no particular temporal or chronological significance unless otherwise indicated. The terms “cause” or “causing” means to make, force, compel, direct, command, instruct, and/or enable an event or action to occur or at least be in a state where such event or action is to occur, either in a direct or indirect manner. The term “set” does not necessarily exclude the empty set—in other words, in some circumstances a “set” may have zero elements. The term “non-empty set” may be used to indicate exclusion of the empty set—that is, a non-empty set must have one or more elements, but this term need not be specifically used. The term “subset” does not necessarily require a proper subset. In other words, a “subset” of a first set may be coextensive with (equal to) the first set. Further, the term “subset” does not necessarily exclude the empty set-in some circumstances a “subset” may have zero elements.

The corresponding structures, materials, acts, and equivalents (e.g., of all means or step plus function elements) that may be in the claims below are intended to include any structure, material, or act for performing the function in combination with other claimed elements as specifically claimed. While the disclosure describes structures corresponding to claimed elements, those elements do not necessarily invoke a means plus function interpretation unless they explicitly use the signifier “means for.” Unless otherwise indicated, recitations of ranges of values are merely intended to serve as a shorthand way of referring individually to each separate value falling within the range, and each separate value is hereby incorporated into the specification as if it were individually recited. While the drawings divide elements of the disclosure into different functional blocks or action blocks, these divisions are for illustration only. According to the principles of the present disclosure, functionality can be combined in other ways such that some or all functionality from multiple separately-depicted blocks can be implemented in a single functional block; similarly, functionality depicted in a single block may be separated into multiple blocks. Unless explicitly stated as mutually exclusive, features depicted in different drawings can be combined consistent with the principles of the present disclosure. Moreover, although this disclosure describes and depicts respective implementations herein as including particular components, elements, feature, functions, operations, or steps (and arrangements thereof), any of these implementations may include any combination, arrangement, or permutation of any of the components, elements, features, functions, operations, or steps described or depicted anywhere herein that a person having ordinary skill in the art would comprehend after reading the present disclosure. Furthermore, reference in the appended claims to an apparatus or system or a component of an apparatus or system being adapted to, arranged to, capable of, configured to, enabled to, operable to, or operative to perform a particular function encompasses that apparatus, system, component, whether or not it or that particular function is activated, turned on, or unlocked, as long as that apparatus, system, or component is so adapted, arranged, capable, configured, enabled, operable, or operative.

The description of the present disclosure has been presented for purposes of illustration and description but is not intended to be exhaustive or limited to the disclosure in the form disclosed. After reading the present disclosure, many modifications, variations, substitutions, and any combinations thereof will be apparent to those of ordinary skill in the art without departing from the scope and spirit of the disclosure. The implementation(s) were chosen and described in order to explain the principles of the disclosure and the practical application, and to enable others of ordinary skill in the art to understand the disclosure for various implementation(s) with various modifications and/or any combinations of implementation(s) as are suited to the particular use contemplated. The features of any dependent claim may be combined with the features of any of the independent claims or other dependent claims.

Having thus described the disclosure of the present application in detail and by reference to implementation(s) thereof, it will be apparent that modifications, variations, and any combinations of implementation(s) (including any modifications, variations, substitutions, and combinations thereof) are possible without departing from the scope of the disclosure defined in the appended claims.

What is claimed is:

1. A method for constructing heat transfer architectures for use in wearables or other small electronic devices using selective micro plating to quickly and precisely generate complex 3D microstructures comprising:
creating capillary wick structures, wherein the capillary wick structures vary in characteristics; and
generate an interface with a vessel wall to provide an optimal interface between the capillary wick structures and the vessel wall.

2. The method of claim 1, wherein the characteristics include at least one of porosity, surface finish, hydrophilicity/hydrophobicity, surface tension, and capillary action.

3. The method of claim 1, wherein the capillary wick structures vary in characteristics along a length of a heat pipe of the capillary wick structures.

4. The method of claim 1, wherein the capillary wick structures vary in characteristics over an area of a vapor chamber of the capillary wick structures, wherein the characteristics include a pore size that is varied over a length of the vapor chamber.

5. The method of claim 1, wherein the selective micro plating is performed on a flat conductive surface and used to generate the capillary wick structures having complex three-dimensional (3D) geometries.

6. The method of claim 1, wherein at least a portion of the heat transfer architectures is shaped in 3D to conform to a shape/elevation of components on a Printed Circuit Board (PCB).

7. The method of claim 1, wherein thermal dissipation whiskers protruding from the heat transfer architectures are added to increase surface area.

8. A heat transfer architecture for use in wearables or other small electronic devices using selective micro plating to quickly and precisely generate complex 3D microstructures comprising:
capillary wick structures, wherein the capillary wick structures vary in characteristics; and
an interface with a vessel wall to provide an optimal interface between the capillary wick structures and the vessel wall.

9. The heat transfer architecture of claim 8, wherein the characteristics include at least one of porosity, surface finish, hydrophilicity/hydrophobicity, surface tension, and capillary action.

10. The heat transfer architecture of claim 8, wherein the capillary wick structures vary in characteristics along a length of a heat pipe of the capillary wick structures.

11. The heat transfer architecture of claim 8, wherein the capillary wick structures vary in characteristics over an area of a vapor chamber of the capillary wick structures, wherein the characteristics include a pore size that is varied over a length of the vapor chamber.

12. The heat transfer architecture of claim 8, wherein the selective micro plating is performed on a flat conductive surface and used to generate the capillary wick structures having complex three-dimensional (3D) geometries.

13. The heat transfer architecture of claim 8, wherein at least a portion of the heat transfer architectures is shaped in 3D to conform to a shape/elevation of components on a Printed Circuit Board (PCB).

14. The heat transfer architecture of claim 8, wherein thermal dissipation whiskers protruding from the heat transfer architectures are added to increase surface area.

15. An electronic device that includes a heat transfer architecture comprising:
an electronic device, wherein the electronic device includes capillary wick structures, wherein the capillary wick structures vary in characteristics; and
an interface with a vessel wall to provide an optimal interface between the capillary wick structures and the vessel wall.

16. The electronic device of claim 15, wherein the characteristics include at least one of porosity, surface finish, hydrophilicity/hydrophobicity, surface tension, and capillary action.

17. The electronic device of claim 15, wherein the capillary wick structures vary in characteristics for one or more of:
along a length of a heat pipe of the capillary wick structures; and
over an area of a vapor chamber of the capillary wick structures, wherein the characteristics include a pore size that is varied over a length of the vapor chamber.

18. The electronic device of claim 15, wherein the selective micro plating is performed on a flat conductive surface and used to generate the capillary wick structures having complex three-dimensional (3D) geometries.

19. The electronic device of claim 15, wherein at least a portion of the heat transfer architectures is shaped in 3D to conform to a shape/elevation of components on a Printed Circuit Board (PCB).

20. The electronic device of claim 15, wherein thermal dissipation whiskers protruding from the heat transfer architectures are added to increase surface area.
